(19) United States
(12) Patent Application Publication
(10) Pub. No.: US 2007/0202688 A1
(43) Pub. Date: Aug. 30, 2007

(54) Method for forming contact opening

(76) Inventors: Pei-Yu Chou, Shulin City (TW); Wen-Chou Tsai, Taoyuan City (TW); Jiunn-Hsiung Liao, Shanhua Township (TW)

Correspondence Address: J.C. Patents, Inc., Suite 250, 4 Venture, Irvine, CA, 92618, US

(21) Appl. No.: 11/361,645

(22) Filed: Feb. 24, 2006

(51) Int. Cl. H01L 21/467

(52) U.S. Cl. 438/637; 438/724; 438/740

(57) ABSTRACT

A method for forming a contact opening is described. A substrate formed with a semiconductor device thereon is provided, and then an etch stop layer, a dielectric layer and a patterned photoresist layer are formed sequentially over the substrate. The exposed dielectric layer and 20% to 90% of the thickness of the exposed etch stop layer are removed to form an opening. After the patterned photoresist layer is removed, an etch step using a reaction gas is conducted to remove the etch stop layer remaining at the bottom of the opening and form a contact opening that exposes a part of the device, wherein the reaction gas is selected from CF₄, CHF₃ and CH₂F₂. By using the method, a micro-masking effect is avoided, and oxidation at the bottom of the contact opening conventionally caused by the photoresist removal using oxygen plasma is also avoided.

### BACKGROUND OF THE INVENTION

1. Field of the Invention

The present invention relates to a semiconductor process. More particularly, the present invention relates to a method for forming a contact opening.

2. Description of the Related Art

In advanced MOS processes, a highly tensile nitride layer is usually formed over the substrate before the ILD layer is formed, also serving as a contact etching stop layer (CESL). When the process linewidth is reduced to 65 nm or below, the CESL can be formed thicker to further increase the Si—Si distance and thereby improve the carrier mobility and the device performance.

FIGS. 1A-1B depict such a contact opening process in the prior art. Referring to FIG. 1A, a substrate 100 with MOS transistors 102, 104 and 106 thereon is provided. A CESL 108 of silicon nitride, an inter-layer dielectric (ILD) layer 110 of silicon oxide and a patterned photoresist layer 111 are formed over the substrate 100. When the linewidth is reduced and the deposition thickness of the CESL 108 is increased, portions of the CESL 108 between the two MOS transistors 104 and 106 are merged, so that the CESL 108 is thicker at the merge part 112 and a seam 113 is naturally formed thereat.

Referring to FIG. 1B, dry etching is conducted, with CH₂F₂ as a reaction gas and the patterned photoresist layer 111 as a mask, to remove exposed portions of the ILD layer 110 and the CESL 108 and form a contact opening 118 between the transistors 104 and 106 as well as a contact opening 120 over the transistor 102. Since the CESL 108 is thicker at the merge part 112, the etching time must be increased. However, because the portion of the CESL 108 in the contact opening 120 is not thicker, the self-aligned silicide (salicide) layer 116 is recessed. In a case where the contact opening 120 is for a contact plug of an S/D region, even the spacer 114 and the isolation layer (not shown) made from SiO are damaged for the reaction gas used in the etching step is CH₂F₂ that does not make a large difference between the etching rates of SiO and SiN.

To completely remove the CESL in all contact openings without these problems, CH₃F can be used instead of CH₂F₂ as a reaction gas for etching the CESL 108. Since using CH₃F as a reaction gas makes the etching rate of the nitride much higher than that of oxide, the spacer and the isolation layer of SiO are little damaged.

Nevertheless, as shown in FIG. 1B, because the oxide also fills in the seam 113 in the CESL 108 at the merge part 112 when the ILD later 110 is deposited and the etching rate of oxide is low with CH₃F as a reaction gas, an oxide micro-mask 110a is formed in the etching step so that a portion 108a of the CESL 108 remains in the contact opening 118. This greatly raises the contact resistance (Rc) or even makes the contact open in the wafer acceptance test (WAT). Moreover, since much polymer by-product is formed when CH₃F is used as a reaction gas, O₂ has to be added into the etching gas to remove the polymer by-product. However, because the salicide layer 116 is readily oxidized by oxygen, the contact resistance is difficult to control.

### SUMMARY OF THE INVENTION

In view of the foregoing, this invention provides a method for forming a contact opening, which can prevent a micro-masking effect when the contact opening is formed through a thicker portion of a CESL between two devices close to each other.

Another object of this invention is to prevent formation of polymer by-product in a contact opening process without the salicide oxidation issue.

The method for forming a contact opening of this invention is described below. A substrate with a semiconductor device thereon is provided, and then an etching stop layer, a dielectric layer, and a patterned photoresist layer are sequentially formed over the substrate, wherein the patterned photoresist layer has therein an opening pattern over the semiconductor device. The patterned photoresist layer is used as a mask to remove the exposed dielectric layer and 20-90% of the thickness of the exposed etching stop layer and form an opening, and is then removed. An etching step is conducted using a reaction gas to remove the etching stop layer remaining at the bottom of the opening and form a contact opening that exposes a part of the semiconductor device, wherein the reaction gas is selected from CF₄, CHF₃ and CH₂F₂.

In the above method, a hard mask layer like a silicon oxynitride (SiON) layer may be further formed on the dielectric layer prior to the patterned photoresist layer. The semiconductor device may be a MOS transistor, which may include a salicide layer on a gate and source/drain regions thereof. The salicide layer may include a material selected from cobalt silicide, titanium silicide, tungsten silicide, tantalum silicide, palladium silicide, platinum silicide, molybdenum silicide, nickel silicide, and nickel alloy silicides including nickel platinum silicide, nickel cobalt silicide and nickel titanium silicide.

Moreover, a first cleaning step may be inserted after the patterned photoresist layer is removed but before the etching step, while a second cleaning step may be added after the etching step. In addition, the material of the etching stop layer may be SiN, and that of the dielectric layer may be SiO.

In one embodiment, the semiconductor device includes two MOS transistors that include two gates and a shared doped region between them, wherein the two gates are disposed close to each other such that a portion of the etching stop layer between the two gates has a larger thickness than other portions of the same. The contact opening is formed through the portion of the etching stop layer to electrically connect the shared doped region, wherein the shared doped region may have a salicide layer thereon.

Accordingly, the CESL is removed in two stages in this invention, wherein 20%-90% of the thickness of the CESL is removed in the first stage and the rest removed in the second stage. Since in the second stage the etching rate difference between the CESL and the dielectric layer is reduced, the contact opening has a better profile and the dielectric material filling in a seam in the CESL between two close devices can be removed to prevent a micro-masking effect.

Moreover, since the photoresist layer is removed before the second stage of CESL etching, there is little polymer residue after the second stage. In addition, since the polymer by-product from the first stage is removed before the second stage, no oxygen needs to be added into the etching gas of the second stage so that a salicide oxidation issue does not occur.

It is to be understood that both the foregoing general description and the following detailed description are exemplary, and are intended to provide further explanation of the invention as claimed.

### BRIEF DESCRIPTION OF THE DRAWINGS

FIGS. 1A and 1B illustrate, in a cross-sectional view, a process flow of a method for forming a contact opening in the prior art.

FIGS. 2A-2D illustrate, in a cross-sectional view, a process flow of a method for forming a contact opening according to an embodiment of this invention.

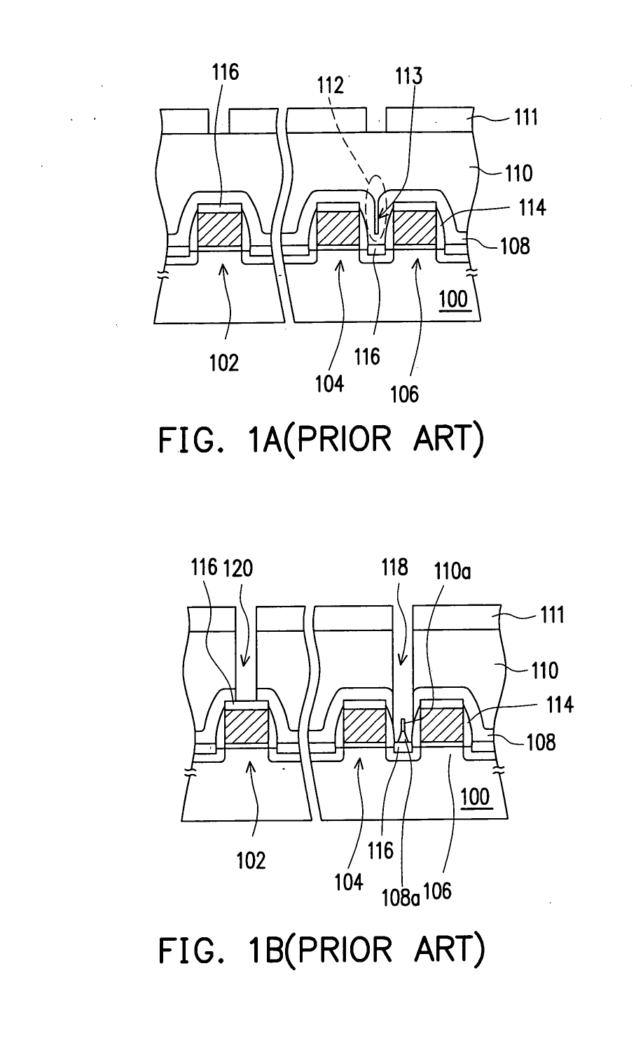

### DESCRIPTION OF THE PREFERRED EMBODIMENTS

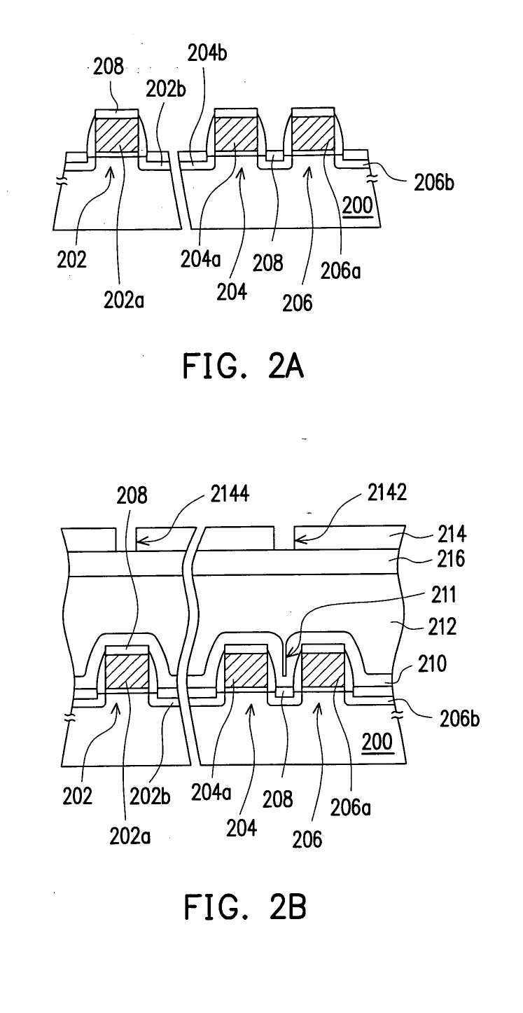

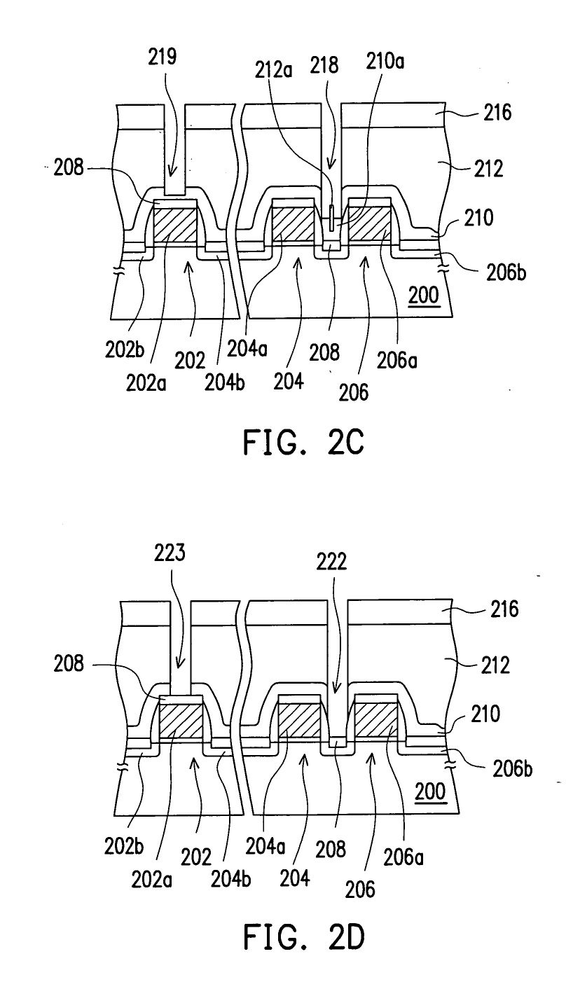

Referring to FIG. 2A, a substrate 200 with semiconductor devices thereon is provided. In this embodiment, the semiconductor devices may include three MOS transistors 202, 204 and 206, wherein the two transistors 204 and 206 are disposed close to each other. A salicide layer 208 is then formed on the gates 202a, 204a and 206a and the source/drain (S/D) regions 202b, 204b and 206b of the transistors 202 to 206.

The salicide layer 208 may include a material selected from cobalt silicide, titanium silicide, tungsten silicide, tantalum silicide, palladium silicide, platinum silicide, molybdenum silicide, nickel silicide, and nickel alloy silicides including nickel platinum silicide, nickel cobalt silicide and nickel titanium silicide. The salicide layer 208 may be formed by depositing a metal layer over the substrate 200, conducting an annealing process to cause a metal-silicon reaction and removing the unreacted metal.

Referring to FIG. 2B, a contact etching stop layer (CESL) 210, a dielectric layer 212 and a patterned photoresist layer 214 are sequentially formed over the substrate 200, wherein the material of the CESL 210 may be SiN that is possible formed through CVD. The deposition thickness of the CESL 210 may be up to about 1000 Å in a small-linewidth process, while the thickness of the portion of the CESL 210 between the two gates 204a and 206a may even reach about 1750 Å because the transistors 204 and 206 are so close to each other. Also, a seam 211 is naturally formed in the portion of the CESL 210. The dielectric layer 212 may include SiO or BPSG, and may be formed through CVD. In addition, a hard mask layer 216 may be formed on the dielectric layer 212 prior to the patterned photoresist layer 214, possibly including SiON and formed through PECVD. The patterned photoresist layer 214 has two openings 2142 and 2144 therein respectively over the S/D region shared by the two transistors 204 and 206 and over the gate 202a of the transistor 202.

Referring to FIG. 2C, the patterned photoresist layer 214 is used as a mask to remove the exposed hard mask layer 216, the exposed dielectric layer 212 and 20-90% of the thickness of the exposed CESL 210, so as to form a opening 218 between the transistors 204 and 206 and another opening 219 over the gate 202a. In one example, the portion 210a of the CESL 210 remaining at the bottom of the opening 218 has a thickness of 800-900 Å, and the portion remaining at the bottom of the opening 219 has a thickness of 200-300 Å. The exposed dielectric layer 212 may be removed with an etching recipe highly selective to SiO, and the reaction gas for removing 20-90% of the exposed CESL 210 may be CH₃F, for example, that has a much higher selectivity to SiN than to SiO. Since CH₃F is uses as a reaction gas, the oxide in the seam 211 cannot be removed completely but forms a micro-mask 212a, and oxygen has to be added into the etching gas to remove the polymer by-product. However, it is particularly noted that the salicide layer 208 is not oxidized in the removal step, because portions of the CESL 210 still remain in the openings 218 and 219.

Then, the patterned photoresist layer 214 is removed by, for example, oxygen plasma ashing. Because portions of the CESL 210 still remain in the openings 218 and 219, the salicide layer 208 is either not oxidized in the ashing. A first cleaning step may be inserted here to remove the residues from the removal step and the ashing step.

Referring to FIG. 2D, an etching step is conducted using the hard mask layer 216 as a mask to remove the CESL 210 remaining at the bottoms of the openings 218 and 219 and expose the salicide layer 208 under them, so that contact openings 222 and 223 are formed. The etching step uses a reaction gas selected from CF₄, CHF₃ and CH₂F₂. Since such a reaction gas makes the SiN-etching rate slightly higher than the SiO-etching rate by, for example, merely five times, the micro-mask 212a can be removed completely. Moreover, since the residues formed from the removal step and the ashing step have been removed before the etching step, no oxygen gas has to be added into the etching gas so that the salicide layer 208 is not oxidized. A second cleaning step may be added after the etching step to remove the polymer by-product in a small amount from the etching step. Thereafter, a conductive material (not shown) is filled into the contact openings 222 and 223 to form corresponding contact plugs.

As mentioned above, since in the above etching step the etching rate difference between the CESL and the dielectric layer is reduced, the contact opening has a better profile and the dielectric material filling in a seam in the CESL between two close devices can be removed to prevent a micro-masking effect. Moreover, since the photoresist layer is removed before the etching step, there is little polymer residue after the etching step. In addition, for the polymer by-product from the previous steps is removed before the etching step, no oxygen needs to be added into the etching gas of the etching step so that a salicide oxidation issue does not occur.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

What is claimed is:

1. A method for forming a contact opening, comprising:
providing a substrate with a semiconductor device thereon;
sequentially forming over the substrate an etching stop layer, a dielectric layer, and a patterned photoresist layer having therein an opening pattern over the semiconductor device;
using the patterned photoresist layer as a mask to remove the exposed dielectric layer and 20-90% of a thickness of the exposed etching stop layer, so as to form an opening;
removing the patterned photoresist layer; and
conducting an etching step with a reaction gas to remove the etching stop layer remaining at bottom of the opening to form a contact opening exposing a part of the semiconductor device, wherein the reaction gas is selected from CF₄, CHF₃ and CH₂F₂.

2. The method of claim 1, further comprising a step of forming a hard mask layer on the dielectric layer before the patterned photoresist layer is formed.

3. The method of claim 2, wherein the hard mask layer comprises SiON.

4. The method of claim 1, wherein the semiconductor device comprises a MOS transistor.

5. The method of claim 4, wherein the MOS transistor includes a salicide layer on a gate and source/drain regions thereof.

6. The method of claim 5, wherein the salicide layer comprises a material selected from cobalt silicide, titanium silicide, tungsten silicide, tantalum silicide, palladium silicide, platinum silicide, molybdenum silicide, nickel silicide, and nickel alloy silicides including nickel platinum silicide, nickel cobalt silicide and nickel titanium silicide.

7. The method of claim 1, further comprising a first cleaning step after the patterned photoresist layer is removed but before the etching step.

8. The method of claim 7, further comprising a second cleaning step after the etching step.

9. The method of claim 1, wherein the etching stop layer comprises silicon nitride.

10. The method of claim 1, wherein the dielectric layer comprises silicon oxide.

11. The method of claim 1, wherein
the semiconductor device comprises two MOS transistors that include two gates and a shared doped region between the two gates;
the two gates are disposed close to each other, such that a portion of the etching stop layer between the two gates has a larger thickness than other portions of the etching stop layer and a seam is formed in the portion of the etching stop layer; and
the contact opening is formed through the portion of the etching stop layer to electrically connect the shared doped region.

12. The method of claim 11, wherein the shared doped region has a salicide layer thereon.
